(19) United States
(12) Patent Application Publication
(10) Pub. No.: US 2012/0118348 A1
(43) Pub. Date: May 17, 2012

(54) METHOD AND APPARATUS TO ENABLE SAFE SERVICING OF PV MODULES

(75) Inventor: Benyamin Buller, Perrysburg, OH (US)

(73) Assignee: FIRST SOLAR, INC.

(21) Appl. No.: 12/946,935

(22) Filed: Nov. 16, 2010

(51) Int. Cl. H01L 31/042; H02H 9/04

(52) U.S. Cl. 136/244; 361/56

(57) ABSTRACT

An apparatus and method for reducing the voltage in a photovoltaic system to allow servicing of solar modules. The apparatus includes a switch that electrically shorts conductors of the system, thereby reducing high voltage conditions at the modules. The apparatus and method can also include use of a detector that measures voltage and/or current in the system to control switch operations.

### FIELD OF THE INVENTION

Embodiments of the invention relate to the field of photovoltaic (PV) power generation systems, containing for example, a plurality of individual power generators, such as solar modules, and more particularly to an apparatus and method of reducing voltage in such a system to allow for safety in servicing of the individual power generators.

### BACKGROUND OF THE INVENTION

Photovoltaic systems are usually comprised of arrays of individual photovoltaic modules. The modules typically have a glass or another transparent substrate that covers and protects an active material that converts incident light into electrical energy. The electrical energy from an individual, or more typically, a plurality of modules is then passed through an inverter and fed into an electric grid. Typically, photovoltaic systems are installed outdoors to enable collection of solar light energy. Being outdoors, the system, and its individual modules, is subject to varying levels of dust and/or dirt that accumulates on the modules to an extent depending on the environment in which the system is installed, weather conditions, and the inclination angle of the modules. As dust and/or dirt collects on the modules, light that would normally interact with the active material and generate electrical energy is blocked. Estimates of the energy lost due to dust and/or dirt accumulations range between 2% and 50% depending on tilt angle of the module, environment, frequency of precipitation, module design, and other factors.

To mitigate the effect of accumulated dust and/or dirt, the individual modules are cleaned, typically during the day. However, cleaning a module during the day can be problematic, because during the day the modules are actively converting solar energy to electrical energy. As a result, the modules are energized and the system containing the modules can be carrying very high voltages, for example, several hundred to a thousand volts or more. The solar modules are each designed so that the external body is completely isolated from the high voltages to which the modules are electrically connected. That said, even the most reliable module packaging is ever 100% reliable. Failures may occur because of cracking in the insulation wiring around a module external conductor, in the glass or transparent substrate, or due to a defect in the module internal insulation. If a failure occurs, the high voltages of the modules and in the system could be discharged during servicing, such as a cleaning operation, particularly, if a module was inadvertently grounded.

During a cleaning process, the likelihood of inadvertently grounding a module is increased because water and other conductive substances are in direct contact with the module. Thus, what is needed is an apparatus and method of reducing high voltages that may be present on a module to allow for servicing, e.g. cleaning, safety.

### BRIEF DESCRIPTION OF THE DRAWINGS

FIG. 1 shows a photovoltaic system that incorporates a switch;

FIG. 2 shows a photovoltaic system that incorporates a switch and a detector;

FIG. 3 shows a photovoltaic system with a solar module array that incorporates a switch;

FIG. 4 shows a photovoltaic system with a solar module array and a plurality of switches;

FIG. 5 shows a photovoltaic system with a solar module array and a switch connected to a network;

FIG. 6 shows a method of reducing high currents in a photovoltaic system;

FIG. 7 shows a photovoltaic system with a solar module array, switch and wireless connectivity;

FIG. 8 shows a photovoltaic system with a solar module array where a switch and inverter are encased together; and

FIG. 9 shows a photovoltaic system with a solar module array and a switch in series and a switch in parallel with an inverter.

### DETAILED DESCRIPTION OF THE INVENTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or other changes may be made to the specific embodiments disclosed without departing from the spirit and scope of the invention.

FIG. 1 shows an example of a photovoltaic system 100 that includes a plurality of solar modules with one such solar module 110 being shown. The system 100 further includes positive and negative outer electrical buses 122, 124, an inverter 130, and a switch 140. Solar module 110 has positive and negative terminals 112, 114 respectively coupled to positive and negative outer buses 122, 124. Inverter 130 has positive and negative couplers 132, 134 respectively connected to positive and negative buses 122, 124.

System 100 further includes switch 140 that includes positive and negative leads 142, 144 electrically connected to respective positive and negative outer electrical buses 122, 124. Switch 140 toggles between an open and closed position. In the closed position, switch 140 electrically connects positive bus 122 to negative bus 124, causing an electrical short between them. In the open position, switch 140 electrically isolates positive bus 122 and negative bus 124. Switch 140 can be any device that can electrically connect and disconnect positive and negative buses 122, 124 in a manner just described. Switch 140 can be a mechanical switch that requires a user to manually open and close it. Switch 140 can also use a motor, hydraulics, electric fields, or magnetic fields to open or close the switch terminals. Switch 140 can also contain a processor that would control whether switch 140 opens or closes when a signal is received from an outside source or from an internal program.

As system 100 is exposed to light, solar modules, such as module 110, convert the light to electrical energy. During normal operation of system 100, switch 140 is open, allowing module 110, and other modules in system 100, to produce a DC voltage across positive and negative terminals 112, 114. As a result, a DC voltage is also produced across positive and negative buses 122, 124, and couplers 132, 134 of inverter 130. Inverter 130 converts the DC voltage to an AC voltage, as is well known.

If, however, switch 140 is closed when module 110 is exposed to light, in an idle system, no voltage is generated across positive and negative terminals 112, 114 because they are shorted together. Instead, individual module 110 generates a current that flows through switch 140 and between positive and negative terminals 112, 114. The generated current is dissipated in module 110. In the real world, a small voltage may be generated across buses 122, 124 because of resistance in module 110, terminals 112, 114, and buses 122, 124. However, this voltage is much less than the voltage generated by system 100 when switch 140 is open. For example, module 110 can be part of a photovoltaic system 100 that generates anywhere between 100 to 1000 volts or more across buses 122, 124 when switch 140 is open depending on the specifics of system 100. On the other hand, when switch 140 is closed, system 100 generates between 0 and 48 volts, and preferably, less than 24 volts.

Without switch 140, system 100 would always generate a voltage when module 110, and other modules connected to buses 122, 124 are exposed to light. While switch 140 is able to reduce the voltage in system 100 when closed, if switch 140 is opened or closed when a voltage exists on or a current is passing through system 100 an electric arc could occur within switch 140.

For example, when switch 140 is open, and system 100 is generating a voltage across buses 122, 124, and then closes, two electrical contacts of switch 140 are brought together and into contact with one another. When the electrical contacts reach a certain proximity to each other, an electric arc can occur between the contacts until the contacts are closed and brought into physical contact. Similarly, when switch 140 is closed a current is flowing through system 100 and the electrical contacts in switch 140. As switch 140 is opened, the electrical contacts are separated and an electric arc can occur between the physically separated contacts until they are separated by an adequate distance to prevent arcing. Thus, arcing can occur whenever switch 140 is opened or closed in a system that has a current or voltage associated with buses 122, 124. The high voltages and large currents typically found in photovoltaic systems can produce electric arcs that are very powerful, for example, up to a 1-megawatt arc. Accordingly, switch 140 should have a design that limits arcing to prevent the arc from causing damage to switch 140 and the system. Alternatively, a switch 140 not designed to handle powerful arcs can be used, if powerful arcs can be prevented from occurring.

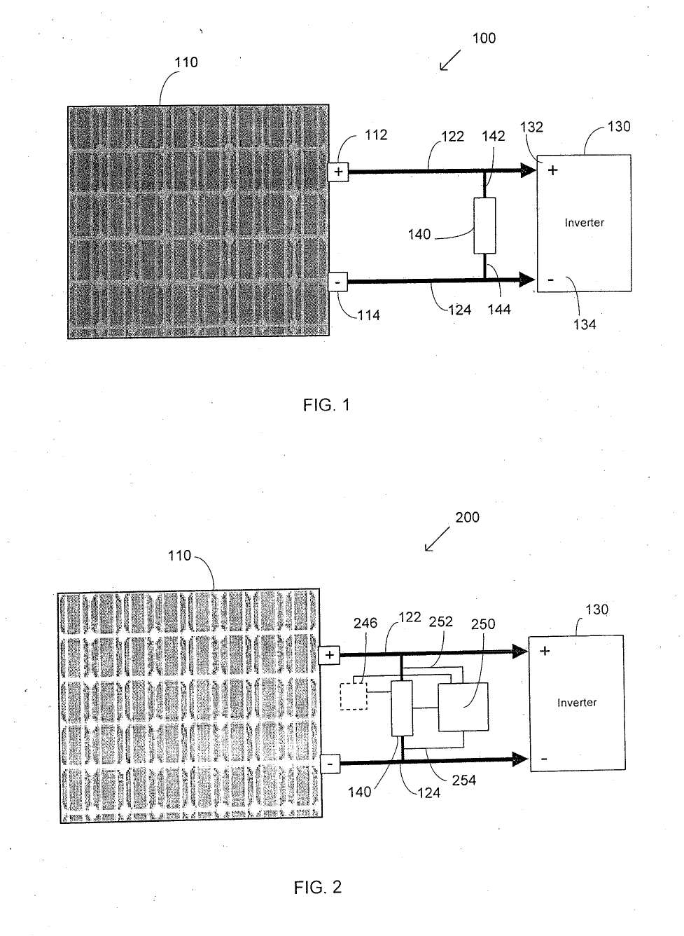

FIG. 2 shows an exemplary photovoltaic system 200 that includes a detector 250 that can be used to prevent undesired electric arcs from occurring in switch 140. All other elements in FIG. 1 are included in FIG. 2. Detector 250 has positive and negative leads 252, 254 that are respectively coupled to buses 122, 124. Detector 250 measures voltage across buses 122, 124 as well as current carried by buses 122, 124.

When undesired electric arcs could occur during operation of switch 140, detector 250 prevents switch 140 from changing positions. For example, if switch 140 is open and detector 250 detects a voltage that could cause damaging arcs, switch 140 is prevented from closing to avoid arcing. In some installations, the voltage and/or current levels are such that detector 250 will only allow switch 140 to be opened or closed at night when voltage and currents are at a minimum.

In some systems, electric arcs of minimal power can be tolerated. In these situations, if detector 250 determines that a voltage and/or current on system 200 is above a threshold that would lead to damaging arcs, it could prevent switch 140 from opening or closing. Various methods can be employed to prevent switch 140 from opening or closing. If switch 140 is manually operated, it could be prevented from opening or closing by using an electric or magnetic solenoid or hydraulic arm that interacts with switch 140, maintaining switch 140 in its current position. Alternatively, if switch 140 uses a motor, hydraulics, electric fields, or magnetic fields to open or close, these methods could be deactivated by disconnecting their control or power feeds. Other methods of preventing switch 140 from opening or closing can also be used.

In one embodiment, to ensure that switch 140 does not open or close when a damaging arc could occur, switch 140 is a programmable switch that is programmed to open or close after receiving a control signal authorizing switch operation from detector 250. For example, switch 140 could be operated from an internal program or can have an associated programmable controller 246, shown in dotted outline in FIG. 2, which receives a control signal from detector 250. Detector 250 can be arranged to continuously monitor voltage, and/or current and determine if conditions are such that switch 140 could be open or closed. After making this determination, detector 250 provides the control signal to switch 140 or an associated switch controller 246, authorizing switch 140 to open or close. Alternatively, switch 140 can send a request directly or through switch controller 246 to detector 250 to monitor voltage and/or current. Detector 250 would determine if conditions are such that switch 140 could be open or closed and then provide an appropriate control signal back to switch 140 directly or through switch controller 246.

Detector 250 can also be used to determine if switch 140 has functioned properly and the voltage on system 200 has been reduced or restored. Further, detector 250 can ensure that switch 140 remains closed by monitoring the voltage across positive and negative buses 122, 124 to ensure that the short circuit is maintained and the voltage stays at a reduced level. Similarly, detector 250 can determine if switch 140 has been properly opened by detecting if current is flowing through switch 140 or if the voltage has been restored between positive and negative buses 122, 124.

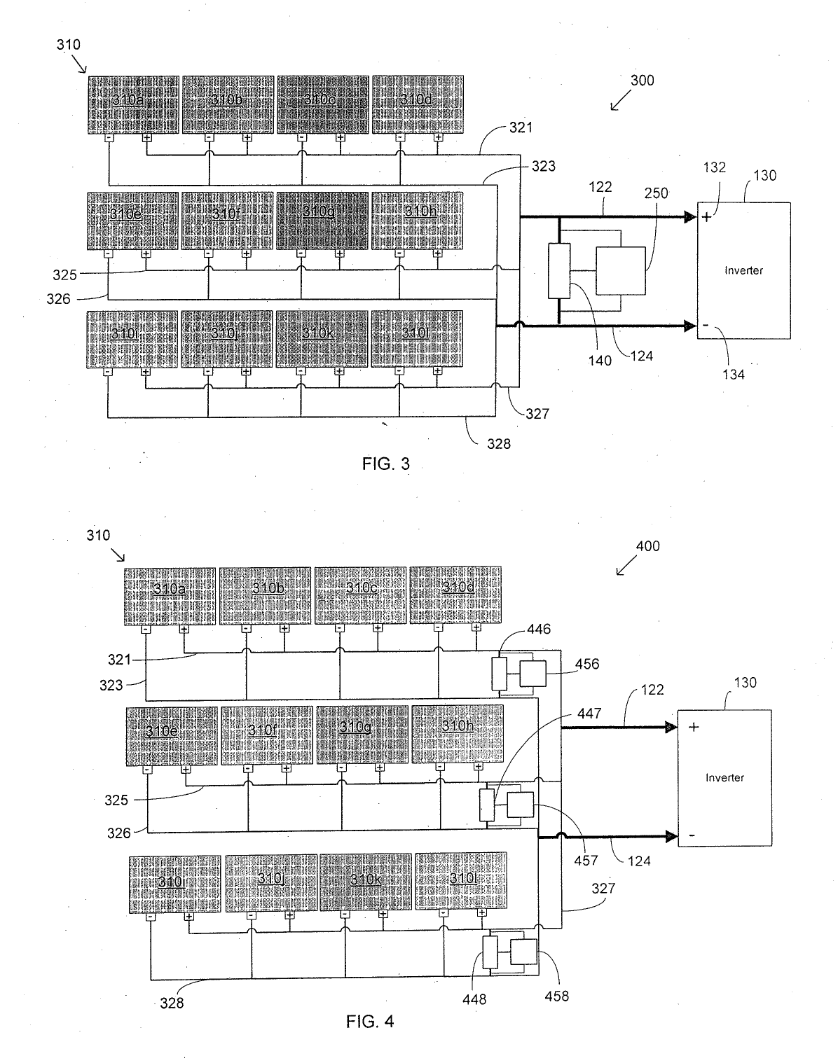

It should be understood that detector 250 can be separate from or integrated within switch 140 in this embodiment as well as the embodiments described with respect to FIGS. 3, 5, 7, and 8.

FIG. 3 shows an exemplary photovoltaic system 300 that includes a plurality of solar modules 310a . . . 310l arranged in groups in a solar module array 310, with the system including inverter 130, switch 140, and detector 250. The positive and negative terminals of solar modules 310a . . . 310d are connected to module positive and negative wires 321, 323. The positive and negative terminals of solar modules 310e . . . 310h are connected to module positive and negative wires 325, 326. The positive and negative terminals of solar modules 310i . . . 310l are connected to module positive and negative wires 327, 328. Module positive wires 321, 325, and 327 are coupled to positive bus 122. Module negative wires 323, 326, and 328 are coupled to negative bus 124. Positive and negative buses 122, 124 are coupled to positive and negative couplers 132, 134, respectively.

Switch 140 is electrically coupled across positive and negative buses 122, 124. Detector 250 is also electrically coupled to positive and negative buses 122, 124. Switch 140 and detector 250 function as previously explained. The voltage on solar module array 310 can vary and depends on how the individual modules are connected in a system. The load capacity of inverter 130 also determines the maximum allowable voltage on a system. Voltages can vary between 100 volts and 1,000 volts or more depending on the design of system 300. The total current in system 300 can also vary between 100 amps to 1,000 amps or more, again depending on the design. Switch 140 needs to be appropriated sized so it can handle the current in system 300. Regardless of the voltage produced by system 300, when switch 140 is closed, the voltage should be no more than 48 volts to prevent injury during module servicing, e.g. cleaning, and preferably less than 24 volts.

Under certain circumstances, switch 140 cannot reduce the voltage throughout all of system 300. For example, if switch 140 is closed, but module negative wire 323 had been previously disconnected from negative bus 124 then the positive and negative terminals of modules 310a-d will not be electrically connected. As a result, the voltage on modules 310a-d would not be reduced. Detector 250 would not detect that the voltage in modules 310a-d had not been reduced because there would be a current flowing through switch 140 produced by modules 310e-l. The embodiment shown in FIG. 4 provides one arrangement for addressing this issue.

FIG. 4 shows an exemplary photovoltaic system 400 that includes a plurality of solar modules 310a . . . 310l arranged in a solar module array 310, with the system including inverter 130, switches 446, 447, 448, and detectors 456, 457, 458. It should be understood that each detector 456, 457, 458 can be separate from or integrated within a respective switch 446, 447, 448. The positive and negative terminals of solar modules 310a . . . 310d are connected to module positive and negative wires 321, 323. The positive and negative terminals of solar modules 310e . . . 310h are connected to module positive and negative wires 325, 326. The positive and negative terminals of solar modules 310i . . . 310l are connected to module positive and negative wires 327, 328. Module positive wires 321, 325, and 327 are coupled to positive bus 122. Module negative wires 323, 326, and 328 are coupled to negative bus 124.

Having multiple switches 446, 447, 448, each associated with a group of modules, e.g. switch 446 associated with the group of modules 310a . . . 310d, switch 447 associated with the group of modules 310e . . . 310h, and switch 448 associated with the group of modules 310i . . . 310l, prevents a problem from occurring if one of module positive wires 321, 325, 327 becomes disconnected from positive bus 122 or if one of module negative wires 323, 326, 328 becomes disconnected from negative bus 124. For example, if module negative wire 323 became disconnected from negative bus 124 it would not affect the ability of switch 446 to reduce the voltage in the group of modules 310a . . . 310d. If switch 446 was closed and module negative wire 323 was disconnected, current from the group of modules 310a . . . 310d would still flow through switch 446 and the voltage on the group of modules 310a . . . 310d would be reduced.

Having multiple switches 446-448 connected across module positive and negative wires 321, 323, 325, 326, 327, 328 also provides redundancy. Because all the positive and negative terminals of solar modules 310a . . . 310l are connected together, even if one of switches 446, 447, 448 were to fail, the remaining switches would still short circuit the positive and negative terminals and reduce the voltage on system 400.

In an alternative embodiment, a switch 140 and a detector 250 could be placed across the positive and negative terminals of every module 310a-l in solar array 310. In another embodiment, only a switch 140 could be placed across the positive and negative terminals of every module 310a-l in solar array 310. It should be understood that any number and combination of switches and detectors could be used between modules and an inverter in a system.

It should also be understood that although the groups of solar modules depicted in FIGS. 3-5, 7, and 8 herein show the modules within a group connected in parallel, and with each group of modules further connected in parallel, that other series and/or parallel connections of solar modules within a group and series and/or parallel connections among groups can be made as well in the embodiments described herein.

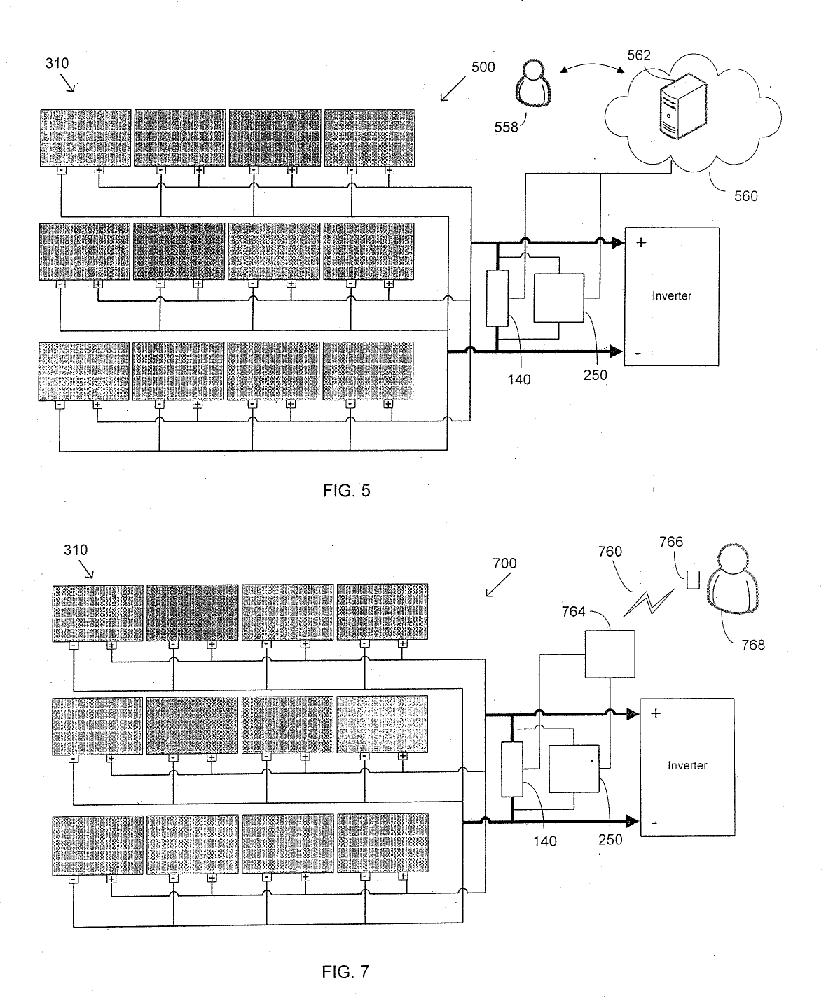

FIG. 5 shows an exemplarily photovoltaic system 500 that is connected to a wired or wireless communications network 560 that is in turn connected to a controller 562. Controller 562 communicates with both switch 140 and detector 250 over network 560. In this embodiment, controller 562 sends control signals to switch 140, which determines when switch 140 opens and closes. Controller 562 also receives information from detector 250 regarding voltage and/or current conditions in system 500. Controller 562 can be configured as a programmed processor.

Controller 562 also allows a user 568 to interact with system 500. For example, a user could input information into controller 562 that solar module array 310 requires servicing, e.g. cleaning, on a certain day or time. User 568 could communicate with controller 562 by sending a text message or email, using a radio, placing a phone call or using any other type of interface or communication. Alternatively, controller 562 could alert user 568 that servicing, e.g. cleaning, needs to be performed on module 110 on a certain day determined by a timetable or based on a reduced efficiency of array 310, which could be determined by detector 250. Controller 562 could alert user 568 of the need for servicing and/or a time and date when switch 140 would be closed by sending user 568 an email, text message, radio message, automated phone call, or through any other form of communication.

A communications network similar to communications network 560 could also be used to control switches 446, 447, 448 and detectors 456, 457, 458 in system 400 described with respect to FIG. 4. A separate controller 562 could be used for each individual switch 446, 447, 448, and/or detectors 456, 457, 458 or a single controller 562 could be used to control all the switches 446, 447, 448 and/or detectors 456, 457, 458.

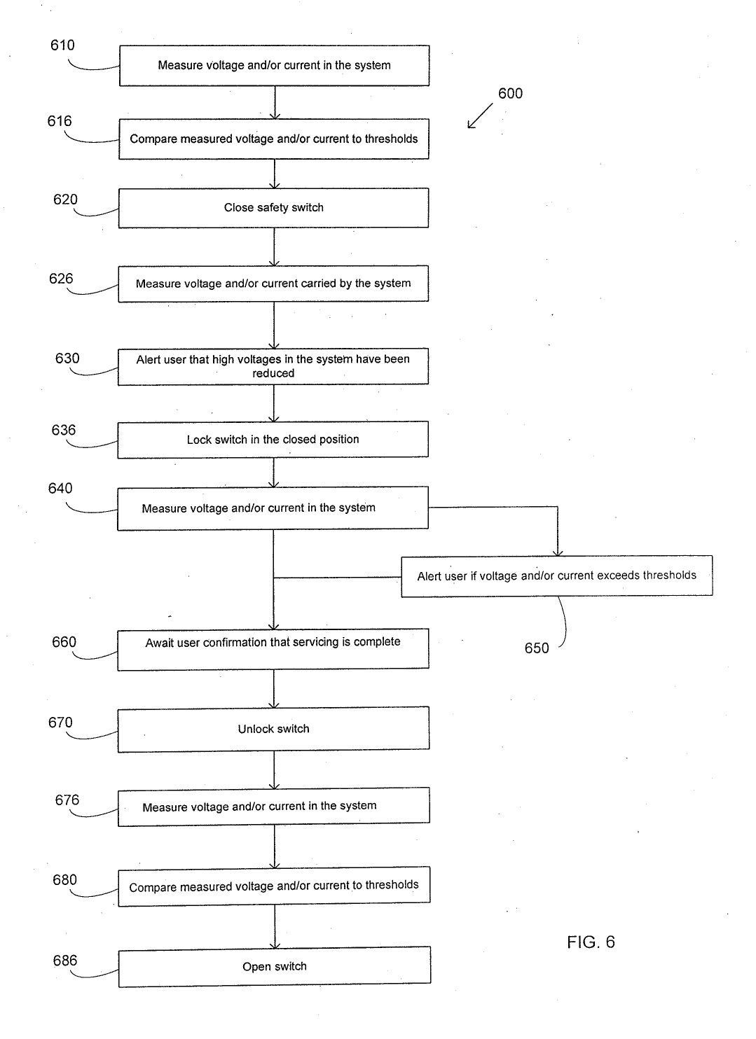

One example of a method of reducing high voltages in system 500 of FIG. 5 is now described with respect to FIG. 6. After receiving notification that servicing was to be performed and the voltage on solar array 310 needed reducing by a communication from user 558 or by a stored timetable or other method, in step 610, controller 562 monitors the voltage and/or current in system 500 using detector 250. In step 616, controller 562 compares the voltage and/or current levels on solar module array 310 to voltage and/or current thresholds to determine if switch 140 can be closed to prevent arcing that could damage switch 140 or other components of system 500. If the voltage and/or current are below the voltage and/or current thresholds, in step 620, controller 562 commands switch 140 to close, electrically shorting buses 122, 124 together.

In step 626, detector 250 measures a voltage across or current carried by buses 122, 124 to verify that buses 122, 124 have been electrically shorted. In step 830, controller 562 receives the voltage and/or current measurements from detector 250 and sends an alert to user 568 indicating that the high voltage levels have been reduced and servicing of one or more modules can commence. User 568 may manually verify that the high voltage levels have been reduced on solar array 310 by measuring the current flowing through the wires of solar array 310 using a current transducer. Controller 562 could alert user 568 by sending user 568 an email, text message, radio message, automated phone call, or through any other form of communication. In step 636, controller 562 locks switch 140 in the closed position. Additionally, controller 562 could require a key or password from user 568 when locking switch 140 in the closed position. In this way, another user could not inadvertently have controller 562 open switch 140 while the servicing was taking place. In step 840, detector 250 continues to measure the voltage across and/or current carried by buses 122, 124 and sends the measurements to controller 562. If the measured voltage and/or current rises above set voltage thresholds, in step 650, controller 562 alerts user 568 of this condition and the process proceeds to step 660. Controller 562 could alert user 568 by sending user 568 an email, text message, radio message, automated phone call, or through any other form of communication.

In step 660, controller 562 waits to receive confirmation from user 568 that the module has been serviced. User 568 could send confirmation to controller 652 through an email, text message, radio message, automated phone call, or through any other form of communication. Upon receiving confirmation, in step 670, controller 562 unlocks switch 140. In step 676, detector 250 measures the voltage and/or current and sends the measurements to controller 662. In step 680, controller 562 compares the measured voltage and/or current to set thresholds to determine if switch 140 can be opened without damaging arcing. If the voltage and/or current are below the set thresholds, in step 686, switch 140 is opened, electrically isolated buses 122, 124 and restoring the high voltage in system 500. It should be understood the above steps are exemplary only of one method to reduce high voltages in system 500 and that additional steps could be performed or some of the above steps omitted to achieve the same result. It should be further understood that in all the described embodiments a user may manually verify that voltage levels have been reduced on a module, a group of modules, or solar array by measuring the current flowing through the conductors connecting the module, group of modules, or the array to an inverter using a current transducer.

FIG. 7 shows another embodiment of an exemplarily photovoltaic system 700 that is connected to a wireless network 760. System 700 includes a controller 764 that communicates with both switch 140 and detector 250. In this embodiment, controller 764 controls when switch 140 opens and closes, and receives information from detector 250 concerning the current and voltage levels on system 700. Controller 764 can also wireless communicate with user 768 through device 766 by radio, bluetooth, or other wireless communications.

A wireless communications network similar to wireless communications network 760 could also be used to control switches 446, 447, 448 and detectors 456, 457, 458 in system 400 described with respect to FIG. 4. Further, a wireless communications network similar to wireless communications network 760 could also be used to control switch 140 and detector 250 in system 500 described with respect to FIG. 5.

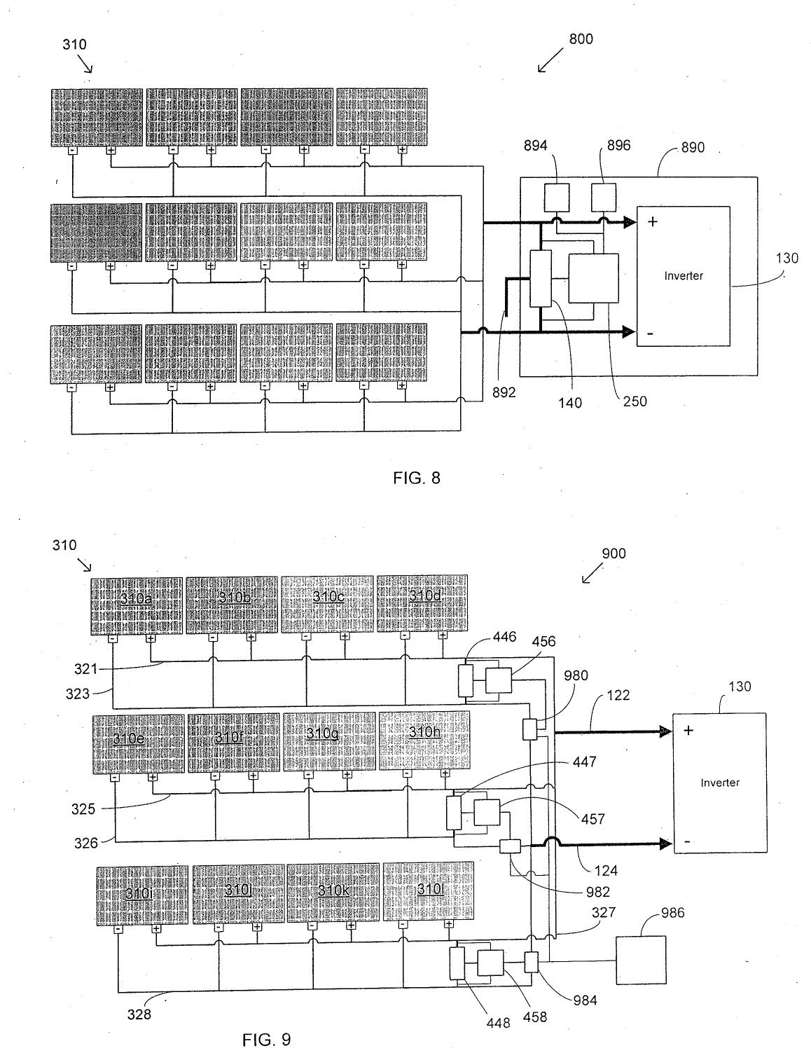

FIG. 8 shows another embodiment of a photovoltaic system 800, where inverter 130, switch 140, and detector 250 are encased in a common housing 890. Housing 890 includes a switch arm 892 that is coupled to switch 140. Switch arm 892 can be toggled between a switched closed position and a switch open position as long as detector 250 allows switch 140 to open or close. Switch arm 892 can also be locked in either position by a locking mechanism such as a pad lock or some other mechanism such as a solenoid or hydraulic arm. As a result, a user that performs service on solar module array 310 in system 800 can close or open switch 140 and lock it in position. The user can then be assured that switch 140 will not inadvertently be opened during the servicing. After performing the servicing on module array 310, the user can then unlock switch 140. Although inverter 130 is shown as being contained within housing 890, it can also be located some distance from housing 890.

In another embodiment, housing 890 can have a keypad 894 and screen 896 located on the housing 890 through which a user can command switch 140 to close and/or lock in the closed position. The locking mechanism could be a solenoid, hydraulic arm or some other mechanism that can lock switch arm 892 in the closed position. Screen 896 indicates when the voltage is reduced in system 800 after receiving feedback from detector 250. After completing the servicing, the user can then unlock switch 140 using keypad 894. After unlocking switch 140, switch 140 can be opened to restore the voltage on system 800.

As previously noted, FIG. 4 shows switches 446, 447, 448 electrically connected to all solar modules 310a . . . 310l in solar module array 310. As a result, any one switch 446, 447, 448, when closed, will short circuit the positive and negative terminals of solar modules 310a . . . 310l, thereby reducing the voltage on all solar modules 310a . . . 310l. However, it may also be desirable that each switch 446, 447, 448, when closed, only reduce the voltage of a group of modules in solar module array 310, and allow a higher voltage to be maintained on the remaining modules.

FIG. 9 shows an exemplary photovoltaic system 900 that includes plurality of solar modules 310a . . . 310l arranged in solar module array 310. System 900 further includes inverter 130, switches 446, 447, 448, and detectors 456, 457, 458 as previously described with respect to FIG. 4. FIG. 9 further shows in-line switches 980, 982, 984. In-line switch 980 is connected in electrical series between the group of modules 310a . . . 310d and their associated switch 446 and inverter 130 along wire 323 and is also connected to detector 456. In-line switch 982 is connected in electrical series between the group of modules 310e . . . 310h and their associated switch 447 and inverter 130 along wire 326 and is also connected to detector 457. In-line switch 984 is connected in electrical series between the group of modules 310i . . . 310l and their associated switch 448 and inverter 130 along wire 328 and is also connected to detector 458. FIG. 9 shows in-line switches 980, 982, 984 between respective switches 446, 447, 448 and inverter 130. In another embodiment, it may be advantageous to have in-line switches 980, 982, 984 between the groups of modules 310a . . . 310d, 310e . . . 310h, 310i . . . 310l and their respective switches 446, 447, 448.

In-line switches 980, 982, 984 are controlled by controller 986 in a manner similar to how controller 562 controls switch 140 with respect to FIG. 5. Alternatively, in-line switches 980, 982, 984 may be controlled by detectors 456, 457, 458, respectively, in a manner similar to how detectors 456, 457, 458 control respective switches 446, 447, 448. In another embodiment, in-line switches 980, 982, 984 may be controlled by detectors that do not control and are not connected to switches 446, 447, 448. It should be understood that many different configurations may be used to control and monitor in-line switches 980, 982, 984.

Having multiple in-line switches 980, 982, 984, each associated with a group of modules, e.g. switch 980 associated with the group of modules 310a . . . 310d, switch 982 associated with the group of modules 310e . . . 310h, and switch 984 associated with the group of modules 310i . . . 310l, allows for the voltage of each group of modules to be separately reduced. For example, if the group of modules 310a . . . 310d needs to be serviced, e.g. cleaned, but groups of modules 310e . . . 310l do not need servicing, the voltage on the group of modules 310a . . . 310d is reduced without reducing the voltage on the groups of modules 310e . . . 310l. In this situation, in-line switch 980 is opened when switch 446 is closed. By opening switch 980, the group of modules 310a . . . 310d and switch 446 are electrically disconnected from the rest of module solar array 310 and inverter 130. As a result, closed switch 446 functions as described above to reduce only the voltage on the group of modules 310a . . . 310d. Once servicing is complete, switch 446 is opened as previously described. In-line switch 980 is closed currently or after switch 446 is opened. With in-line switch 980 closed, the group of modules 310a . . . 310d is again electrically connected to solar module array 310 and inverter 130.

While embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

What is claimed as new and desired to be protected by Letters Patent of the United States is:

1. A photovoltaic system comprising:
at least one solar module electrically connected to a pair of conductors; and
a switch electrically connected across the conductors, the switch in a closed position electrically shorting the conductors, and the switch in an open position electrically isolating the conductors.

2. The photovoltaic system of claim 1, further comprising an inverter, wherein the switch is located between the at least one solar module and the inverter.

3. The photovoltaic system of claim 1, further comprising a detector for measuring at least one of a voltage across the conductors or a current carried by the conductors.

4. The photovoltaic system of claim 3, wherein the detector measures the voltage across the conductors, wherein when the switch is in the open position, the switch is prevented from closing if the measured voltage exceeds a voltage threshold value.

5. The photovoltaic system of claim 3, wherein the detector measures the current carried by the conductors, wherein when the switch is in the open position, the switch is prevented from closing if the measured current exceeds a current threshold value.

6. The photovoltaic system of claim 3, wherein the detector measures the voltage across the conductors, wherein when the switch is in the closed position, the switch is prevented from opening if the measured voltage exceeds a voltage threshold value.

7. The photovoltaic system of claim 3, wherein the detector measures the current carried by the conductors, wherein when the switch is in the closed position, the switch is prevented from opening if the measured current exceeds a current threshold value.

8. The photovoltaic system of claim 3, further comprising a switch controller for controlling operation of the switch.

9. The photovoltaic system of claim 8, wherein the switch controller receives at least one of a voltage or current measurement from the detector.

10. The photovoltaic system of claim 9, wherein the switch controller prevents the switch from opening or closing based on the at least one of voltage or current measurement from the detector.

11. The photovoltaic system of claim 9, wherein the switch controller alerts a user if the at least one of voltage and/or current rises above thresholds after the switch is closed.

12. The photovoltaic system of claim 11, wherein the user is alerted over a network.

13. The photovoltaic system of claim 8, wherein the switch controller locks the switch upon receipt of a password from a user.

14. The photovoltaic system of claim 13, wherein the switch controller unlocks the switch upon receipt of the password from the user.

15. The photovoltaic system of claim 8, further comprising a user operated device for communicating with the switch controller.

16. The photovoltaic system of claim 8, wherein the switch controller communicates with the switch over a network.

17. The photovoltaic system of claim 9, wherein the switch controller communicates with a user over a network.

18. The photovoltaic system of claim 17, wherein the network is wireless.

19. The photovoltaic system of claim 8, wherein the switch controller alerts a user that the switch has been closed.

20. The photovoltaic system of claim 1, further comprising an array of solar modules connected to the positive and negative conductors.

21. The photovoltaic system of claim 20, wherein said array of solar modules further comprises a plurality of groups of solar modules.

22. The photovoltaic system of claim 21, further comprising a plurality of switches, each switch in the plurality of switches electrically connected across one group of solar modules in the plurality of groups of solar modules.

23. The photovoltaic system of claim 22, further comprising a plurality of detectors, each detector for measuring at least one of a voltage across one group of solar modules in the plurality of groups of solar modules.

24. The photovoltaic system of claim 22, further comprising a switch controller for controlling the plurality of switches.

25. The photovoltaic system of claim 21, wherein the plurality of groups of solar modules are connected in series.

26. The photovoltaic system of claim 21, wherein the plurality of groups of solar modules are connected in parallel.

27. The photovoltaic system of claim 21, wherein the plurality of groups of solar modules are connected in a combination of series and parallel connections.

28. The photovoltaic system of claim 22, further comprising a plurality of in-line switches, each in-line switch in the plurality of in-line switches being electrically connected in series between one group of solar modules in the plurality of groups of solar modules and an inverter.

29. The photovoltaic system of claim 28, further comprising a controller for commanding each in-line switch of the plurality of in-line switches to open or close.

30. The photovoltaic system of claim 2, wherein the switch further comprises a manually operable switch arm that can toggle the switch between the open and closed position.

31. The photovoltaic system of claim 30, wherein the switch arm further comprises a locking mechanism for preventing the switch from toggling between the open and closed position.

32. The photovoltaic system of claim 31, wherein said locking mechanism locks and unlocks the switch arm in response to a user entering a password.

33. A photovoltaic system comprising:
an inverter;
an array of solar modules;
an plurality of positive and negative conductor pairs, where each positive and negative conductor pair is connected to at least one solar module within the array of solar modules;
a first conductor connected to and between the positive conductors and the inverter;
a second conductor connected to and between the negative conductors and the inverter;
at least one switch electrically connected across one pair of the first and second conductors, the at least one switch in a closed position electrically shorting the first and second conductors, and the at least one switch in an open position electrically isolating first and second conductors.

34. The photovoltaic system of claim 33, further comprising a plurality of switches, where each switch in the plurality of switches is electrically connected across one positive and negative wire pair.

35. The photovoltaic system of claim 33, wherein each conductor pair is connected to a plurality of solar modules.

36. The photovoltaic system of claim 33, further comprising a detector for measuring at least one of a voltage across or current carried by the conductor pair coupled to the at least one switch.

37. The photovoltaic system of claim 34, further comprising a plurality of detectors, each detector of the plurality of detectors for measuring at least one of a voltage across or current carried by each conductor pair coupled to one of the plurality of switches.

38. The photovoltaic system of claim 33, further comprising a controller for commanding the at least one switch to open or close.

39. The photovoltaic system of claim 34, further comprising a controller for commanding each switch of the plurality of switches to open or close.

40. The photovoltaic system of claim 34, further comprising a plurality of in-line switches, each in-line switch in the plurality of in-line switches electrically connected in series between one group of solar modules in the plurality of groups of solar modules and the inverter.

41. The photovoltaic system of claim 40, further comprising a controller for commanding each in-line switch of the plurality of in-line switches to open or close.

42. A method for reducing high voltage levels in a photovoltaic system comprising:
closing a switch to electrically short conductors to reduce a voltage across the conductors, the conductors being electrically connected to solar modules.

43. The method of claim 42, further comprising measuring at least one of a voltage across the conductors or a current carried by the conductors when the switch is open.

44. The method of claim 43, wherein the switch is closed only after the measured voltage and/or current is below set thresholds.

45. The method of claim 42, further comprising indicating to a user that the voltage level has been reduced.

46. The method of claim 45, wherein the indication is sent over a wireless-network to the user.

47. The method of claim 42, further comprising locking the switch in its current position.

48. The method of claim 47, wherein the switch is locked after receiving a password from a user.

49. The method of claim 47, further comprising unlocking the switch.

50. The method of claim 49, wherein the switch is unlocked after receiving a password from a user.

51. The method of claim 42, wherein the switch is closed with a switch controller.

52. The method of claim 42, wherein the switch is closed manually.

53. The method of claim 42, further comprising measuring at least one of a voltage across the conductors or a current carried by the conductors while the switch is closed.

54. The method of claim 52, further comprising sending an indication to a user if the measured voltage and/or current exceeds set thresholds.

55. The method of claim 54, wherein the indication is sent over a wireless-network to the user.

56. The method of claim 42, further comprising opening the switch after the switch has been closed to restore the voltage across the conductors.

57. The method of claim 56, further comprising measuring at least one of a voltage across the conductor or a current carried by the conductors when the switch is closed.

58. The method of claim 57, wherein the switch is opened only after the measured voltage and/or current is below set thresholds.
